(19) United States
(12) Patent Application Publication
(10) Pub. No.: US 2011/0120518 A1
(43) Pub. Date: May 26, 2011

(54) Manufacturing Photovoltaic Devices And Devices Formed

(75) Inventor: Thomas F. Rust, Berkeley, CA (US)

(73) Assignee: Photon Energy Systems, Berkeley, CA (US)

(21) Appl. No.: 12/911,628

(22) Filed: Oct. 25, 2010

Related U.S. Application Data
(60) Provisional application No. 61/254,678, filed on Oct. 24, 2009.

(51) Int. Cl. H01L 31/042; H01L 31/028; H01L 31/0224; H01L 31/18; H01L 31/0236

(52) U.S. Cl. 136/244; 136/261; 136/256; 438/57; 438/98; 438/72; 257/E31.011; 257/E31.124; 257/E31.13; 257/E31.001

(57) ABSTRACT

Photovoltaic cells can be manufactured using a pattern region that substantially covers the usable surface area of a crystalline workpiece. Bars can be etched into the workpiece that extend substantially the entire length of the workpiece. These bars then can be diced to form die or micro-tiles having a width substantially equal to the thickness of the workpiece, and having an edge ratio of about 20:1 or less. Such a process can maximize conversion area, thereby extracting more energy from a given volume of photovoltaic conversion material. Contacts can be placed on opposing edges of the die or micro-tiles to form photovoltaic cells, which in some embodiments can function regardless of orientation in a solar panel.

### CROSS-REFERENCE TO RELATED APPLICATIONS

This application claims the benefit of, and priority to, U. S. Provisional Patent Application Ser. No. 61/254,678, filed on Oct. 24, 2009, entitled “MANUFACTURING PHOTOVOLTAIC DEVICES,” the entire disclosure of which is hereby incorporated herein by reference. This application is also related to co-pending U.S. patent application Ser. No. 11/525,562, filed Sep. 21, 2006, entitled “SYSTEMS AND METHODS FOR MANUFACTURING PHOTOVOLTAIC DEVICES,” the entire disclosure of which is hereby incorporated herein by reference.

### TECHNICAL FIELD

In general, embodiments of the present invention relate to methods of manufacturing photovoltaic devices and devices formed. In some embodiments, methods of manufacturing are provided that promote maximize conversion area of the starting substrate material, thereby extracting more energy from a given volume of photovoltaic conversion material. Photovoltaic devices are provided that include contacts formed on opposing edges of a silicon die to form photovoltaic cells.

### BACKGROUND

A photovoltaic device is a semiconductor device typically used for converting solar radiation into electrical energy. Solar photovoltaic systems to this point have not been used extensively in power supplying applications due primarily to the high cost of these systems. The high cost is due in part to the relatively high cost of the pure single crystal silicon material that typically is used in these devices. Much of this silicon is wasted in the manufacturing of these devices, thereby increasing the material cost. Further, the cost of the photovoltaic processing itself is not particularly cost effective for many applications. Alternatives to silicon have been studied, but have been found to either produce less efficient devices or to cost more to manufacture.

Prior art solar panels typically are assembled using machinery to precisely position a large number of photovoltaic cells on a substrate, which can be expensive and very time intensive. The length of these cells also can cause problems with jamming, clustering, and breaking during processing. Problems with know fabrication techniques include the use of processing tools operated under vacuum, the use of silane, a highly combustible gas, and the requirement for complex and costly robotic tools in the assembly process, among others. While developments have been made further innovation, particularly innovations that reduce the cost and increase the efficiency of manufacturing of photovoltaic cells and systems, are needed.

### SUMMARY

In some embodiments a photovoltaic cell is provided, comprising a silicon die or “micro-tile” having at least two oppositely doped regions forming a diode; and a pair of contacts on a common edge of the silicon micro-tile. The pair of contacts may be formed on one of the top or rear edges of the silicon micro-tile and on at least one opposing side edge of the silicon micro-tile. In some embodiments the silicon micro-tile further includes an emitter around at least a portion of the, or the entire, circumference of the silicon micro-tile.

In many embodiments, but not exclusively, the silicon micro-tile is comprised of crystalline silicon, and preferably comprised of crystalline silicon having at least one surface with a crystalline orientation of <1,1,0>.

Of particular advantage, in some embodiments a photovoltaic cell is provided wherein the silicon micro-tile is selectively doped. For example, in some embodiments at least one of the top, rear and opposing side edges of the silicon micro-tile exhibits an independent dopant profile. In some embodiments the front or top surface is lightly doped to enhance absorption of the blue portion of the solar spectrum, while the rear and opposing side surfaces are more heavily doped to increase the current path to the back of the cell where the metal contacts reside.

In another aspect, embodiments of the present invention provide a photovoltaic cell comprising: an elongated silicon micro-tile having at least two oppositely doped regions forming a diode, wherein one of these doped regions is an emitter wrapped around or encircling the substantial circumference of the silicon micro-tile. This configuration, using a wrapped emitter provides a conductive path to the back of the cell.

In a further aspect, embodiments of the present invention also provide a solar panel, comprising a plurality of rectangular photovoltaic cells, each photovoltaic cell having at least two oppositely doped regions forming a diode, each photovoltaic cell further having a pair of contacts on a common edge of the cell; a substrate for receiving the plurality of rectangular photovoltaic cells; and an interconnect layout electrically connecting the plurality of rectangular photovoltaic cells. In some embodiments the substrate is comprised of a flexible material. In some embodiments the interconnect layout includes one or more bypass diode circuits.

In another aspect, methods of manufacturing or fabricating photovoltaic cells are also provided. In one exemplary embodiment, a method of forming photovoltaic cells comprised of one or more or an array of micro-tiles is provided comprising the steps of: etching a plurality of slots in at least a portion of a crystalline silicon material to form a plurality of elongated, substantially parallel micro-tiles extending from one edge of the silicon material through substantially to the other edge of the silicon material; and forming a hinge selectively on at least one edge of the silicon material. The hinge may engage such that the plurality of micro-tiles are separated from the crystalline silicon material in long strips. In some embodiments, the plurality of micro-tiles are separated in a fanfold like manner, meaning that the micro-tiles are pulled from the crystalline silicon material similar to the manner by which one would unfold a fan (such as a paper Chinese style fan).

In some embodiments, the micro-tiles are then separated from the hinge to form a plurality of silicon micro-tiles. The silicon micro-tiles may be loaded on a temporary substrate. In some embodiments the silicon micro-tiles are each loaded on the temporary substrate in a random orientation with respect to the other silicon micro-tiles.

Once the silicon micro-tiles are loaded on the temporary substrate they may be further processed. In some embodiments the method further comprises forming contacts on at least one of the top, rear, and side edges of one or more of the silicon micro-tiles. Additionally, at least one dopant may be applied to at least one surface of the silicon micro-tiles. Optionally, at least one surface of the silicon micro-tiles may be textured, and/or an antireflective coating may be deposited on at least one surface of the silicon micro-tiles.

Methods of the present invention provide significant flexibility in manufacture. For example in some embodiments at least one surface of at least one of the silicon micro-tiles may be selectively doped to provide photovoltaic cells with different dopant profiles on one or more of its surfaces,

### BRIEF DESCRIPTION OF THE DRAWINGS

Various embodiments in accordance with the present invention will be described with reference to the drawings, in which:

FIGS. 1A and 1B are side views illustrating a photovoltaic cell assembly with point rear contacts in accordance with two alternative embodiments;

FIG. 2A is a side view showing a photovoltaic cell assembly with textured front surface and rear contacts in accordance with one embodiment;

FIG. 2B is a bottom view of the photovoltaic cell assembly of FIG. 2A in accordance with one embodiment;

FIG. 2C is a bottom view illustrating a photovoltaic cell assembly in accordance with another embodiment;

FIG. 2D is a bottom view showing a photovoltaic cell assembly in accordance with yet another embodiment;

FIG. 3A illustrates a wafer assembly with slots cut to form cell regions in accordance with one embodiment;

FIG. 3B illustrates a wafer assembly with slots cut to form cell regions and indicators for dicing the cells from the wafer in accordance with one embodiment;

FIG. 4A illustrates a side view of a mask material and block of solar cell material to be etched in accordance with one embodiment;

FIG. 4B illustrates a side view of a mask material and block of solar cell material after etching in accordance with one embodiment;

FIG. 5 shows a side view of a combined mask and hinge material and series of solar cells after etching and after unfolding in accordance with one embodiment;

FIG. 6 illustrates a side view of a flexible hinge material and series of solar cells after etching with mask and light source in accordance with one embodiment;

FIG. 7 depicts a side view of a flexible hinge material and series of solar cells after etching after removal of excess hinge material in accordance with one embodiment;

FIG. 8 shows a side view of an additional flexible hinge material and series of solar cells after etching after removal of excess hinge material with mask and light source in accordance with one embodiment;

FIG. 9 illustrates a side view of an additional flexible hinge material and series of solar cells prior to unfolding in accordance with one embodiment;

FIG. 10 illustrates a partial top view of an additional flexible hinge material configuration and series of solar cells prior to unfolding in accordance with one embodiment;

FIG. 11 illustrates a partial top view of an additional flexible hinge material configuration and series of solar cells prior to unfolding in accordance with another embodiment; and

FIG. 12 illustrates a partial top view of an additional flexible hinge material configuration and series of solar cells prior to unfolding in accordance with yet another embodiment.

### DETAILED DESCRIPTION

It is to be understood that both the foregoing general description and the following description are exemplary and explanatory only and are not restrictive of the methods and devices described herein. In this application, the use of the singular includes the plural unless specifically state otherwise. Also, the use of “or” means “and/or” unless state otherwise. Similarly, “comprise,” “comprises,” “comprising,” “include,” “includes” “including” “has” and “ having” are not intended to be limiting. Further, some terms are used interchangeably, such as “photovoltaic” and “solar;” as well as “die” and “micro-tiles.”

The accompanying drawings, which are incorporated into this specification, illustrate one or more exemplary embodiments of the inventions disclosed herein and, together with the detailed description, serve to explain the principles and exemplary implementations of these inventions. One of skill in the art will understand that the drawings are illustrative only, and that what is depicted therein may be adapted based on the text of the specification or the common knowledge within this field.

Systems and methods in accordance with various embodiments of the present invention can overcome the aforementioned and other limitations in existing photovoltaic devices and device manufacturing approaches. In general, methods in accordance with one embodiment utilize the crystalline structure of the materials used in the process, such as <1,1,0> oriented silicon crystals, by etching thin, small die which further incorporate structures to convert photons to electrical energy, as well as to interface to various electrical systems. Crystalline silicon wafers or substrates with silicon crystals in such an orientation can be used as described herein to create narrow, high aspect ratio solar cells by generating die or “micro-tiles” that run substantially the length of the wafer, minus any dividing bars as described below. These micro-tiles are then diced into square or rectangular cells. In one embodiment the cells are rectangular and have an edge ratio, such as length to width (L:W), of about 20:1 or less, and preferably 3:1 or less in one embodiment. Methods in accordance with various embodiments also can include steps for assembling these cells rapidly onto substrates, and incorporating interconnect layouts that allow the die to be assembled in random orientations. Such processes can be advantageous, as well as simpler and cheaper than existing processes for forming photovoltaic devices.

Methods of fabricating photovoltaic cells and modules in accordance with various embodiments of the present invention can produce devices with high efficiency and low cost per energy conversion area. These methods also can maximize the utilization of various materials relative to other solar cell fabrication techniques. Similar approaches can be used, including methods focused on simplicity and low cost, or methods that are more complicated but utilize low temperature pastes and materials, thereby greatly expanding the number of substrates and materials that can be used. In some embodiments, a solar cell is provided comprising a set of contacts with doped regions formed on the “rear” side of the cell.

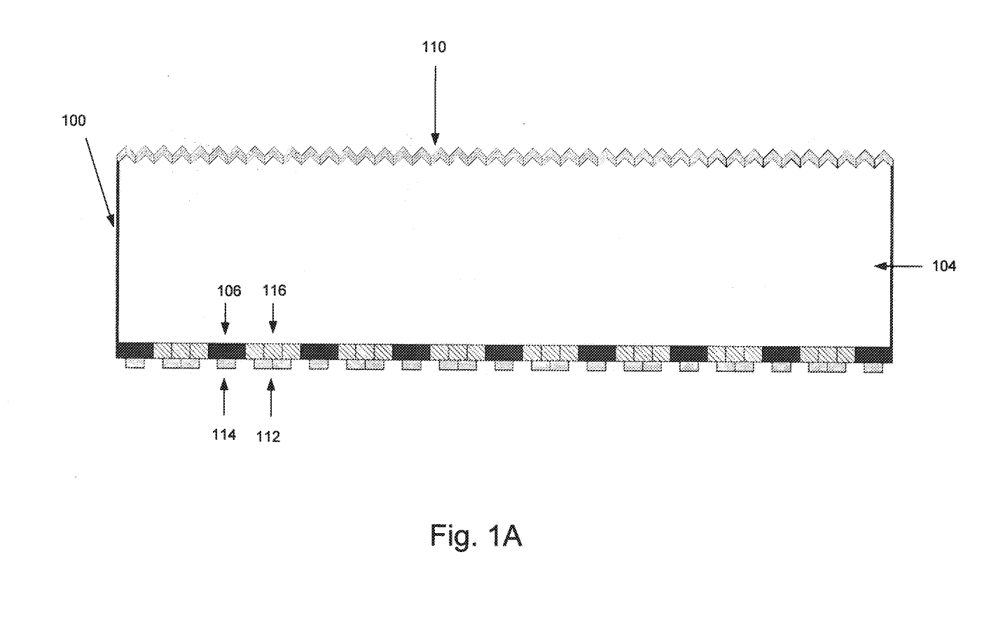

In various embodiments, the individual cells are fabricated in a rectangular pattern from <1,1,0> silicon crystal material. The cells formed in this example are front/back and side/side symmetric, such that the front and rear views are substantially identical. An example of such a photovoltaic cell 100 is shown in FIG. 1A. This particular view shows the bulk material 104, with a thickness that is determined primarily by the thickness of the silicon wafer or other material used to form the die or micro-tile. Generally, but not exclusively, the terms die or micro-tile(s) are used to describe thin pieces of silicon or other material, and the term cell(s), silicon cell, or photovoltaic cell are used once the material has been processed into a functional photovoltaic device. It can be desired for some embodiments that the thickness be greater than that of a standard silicon wafer. Orientations and directions such as “top,” “front,” “back,” “rear,” “upper,” and “lower” are merely used for convenience and simplicity of explanation, and are not meant to infer any requirements of directionality or orientation.

FIG. 1A is not to scale, as each of these regions would typically be thinner relative to the thickness of the bulk silicon 104. While in at least some embodiments it is preferred that the wafer be thicker, as having larger cells can be more efficient and require less processing, thicker wafers also can require longer etches, which can result in an undesirable amount of undercutting. In one embodiment the thickness of the bulk silicon wafer can be on the order of about 1-2 mm.

In some embodiments, the bulk silicon material is lightly doped, or is undoped. The front surface of the cell is textured, using a wet etch or dry etch process. As will be discussed below, a layer of anti-reflective coating (ARC) 110 is formed on the front side of the cell. The antireflective coating can be a silicon or titanium nitride or oxide layer, for example. In some embodiments a paste containing a dopant of opposite polarity to the bulk dopant is applied in bars or dots on the rear side of the cell over region 106. Optionally a paste containing a dopant of the same polarity to the bulk dopant is applied in bars or dots on the rear side of the cell over region 116. The dopant(s) are fired at an elevated temperature (for example in the range of 800 to 1200 C) to drive the dopant into the regions 106. A layer of paste 112, such as a paste containing a conductive material such as silver and a doping material such as aluminum, is printed in dots or bars or otherwise applied to the “rear” of the cell and dried. A second paste 114 containing a conductive material such as silver and optionally an opposite doping material such as phosphorus is printed in dots or bars or otherwise applied in at least one region over the doped region 106, then dried. The cell with the two pastes is then fired at an elevated temperature. This temperature will vary depending on the composition of the paste. In some embodiments the firing temperature is in the range of about 800 to 1200 C The metal containing paste creates a region of doping 116, for example p-doping, so that the aluminum paste effectively contacts the bulk of the silicon 104. The second paste contacts the doped region 106.

It should also be understood that phosphorus doping is merely exemplary, and that devices in accordance with various embodiments can use any appropriate combination of a region of a first doping type and a second doping layer (or region) of a second doping type, where the second dopant is of opposite doping relative to the first dopant.

In some embodiments, the bulk silicon material is lightly doped, or is undoped. The front surface of the cell is textured, using a wet etch or dry etch process. A paste containing a dopant of opposite polarity to the bulk dopant is applied to one side of the cell. A paste containing a dopant of opposite polarity to the bulk dopant is applied in bars or dots on the rear side of the cell over the region 106. Optionally a paste containing a dopant of the same polarity to the bulk dopant is applied in bars or dots on the rear side of the cell over the region 116. The dopant(s) are fired at an elevated temperature to drive the dopant into the regions 106. A layer of a paste 112, such as a paste containing a conductive material such as silver and a doping material such as aluminum, is printed in dots or bars or otherwise applied to the “rear” of the cell and dried. A second paste 114 containing a conductive material such as silver and optionally an opposite doping material such as phosphorus is printed in dots or bars or otherwise applied in at least one region over the doped region 106, then dried. The cell with the two pastes is then fired at an elevated temperature. The metal containing paste creates a region of a doping 116, for example a p-doping, so that the aluminum paste effectively contacts the bulk of the silicon 104. The second paste contacts the doped region 106.

As will be discussed below, a layer of anti-reflective coating (ARC) 110 is formed on the front side of the cell. The antireflective coating can be a silicon or titanium nitride or oxide layer, for example.

Of particular advantage, in some embodiments a photovoltaic cell is provided having a wrapped emitter. The wrapped emitter may extend around a portion of, or alternatively around the substantial portion of or the entirety of, the cell. One embodiment of a wrapped emitter is shown in FIG. 1B. In this embodiment the bulk silicon material is lightly doped, or is undoped. The front surface of the cell is textured, using a wet etch or dry etch process. A paste containing a dopant of opposite polarity to the bulk dopant is applied to the entire front side of the cell and also the sides of the cell 130. A paste containing a dopant of opposite polarity to the bulk dopant is applied to the rear side of the cell as bars or dots on the rear side of the cell over the region 136. Optionally a paste containing a dopant of the same polarity to the bulk dopant is applied in bars or dots on the rear side of the cell over the region 146. Optionally a paste containing a diffusion barrier material is applied in bars or dots on the rear side of the cell over the region 146. The dopant(s) are fired at an elevated temperature to drive the dopant into the regions 136. A layer of a paste 142, such as a paste containing a conductive material such as silver and a doping material such as aluminum, is printed in dots or bars or otherwise applied to the “rear” or bottom surface of the cell, and then dried. A second paste 144 containing a conductive material such as silver and optionally an opposite doping material such as phosphorus is printed in dots or bars or otherwise applied in at least one region over the doped region 136, then dried. The cell with the two pastes is then fired at an elevated temperature. The metal containing paste creates a region of doping 146, for example a p-doping, so that the aluminum paste effectively contacts the bulk of the silicon 134. The second paste contacts the doped region 136

As will be discussed below, a layer of anti-reflective coating (ARC) 140 is formed on the front side of the cell. The antireflective coating can be a silicon, titanium nitride or oxide layer, for example.

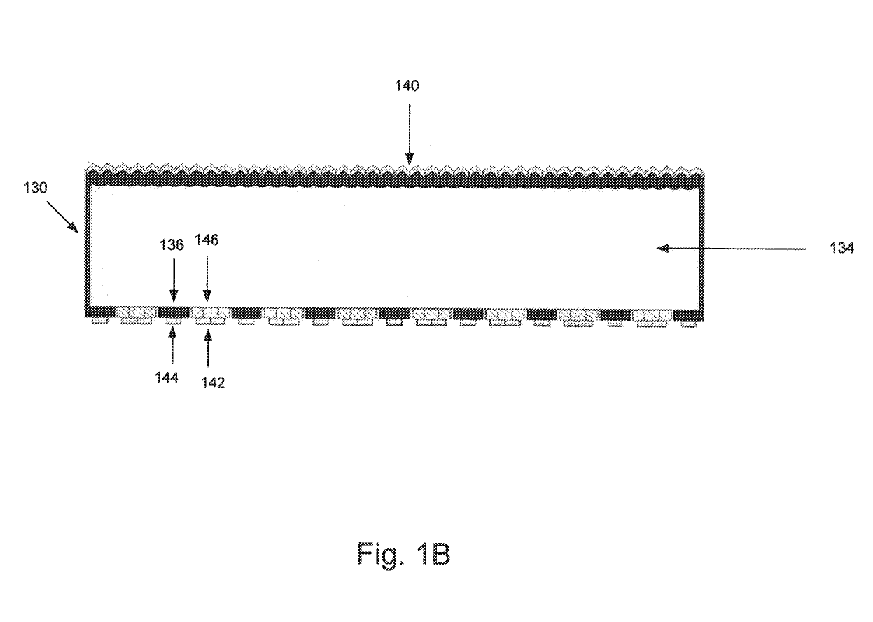

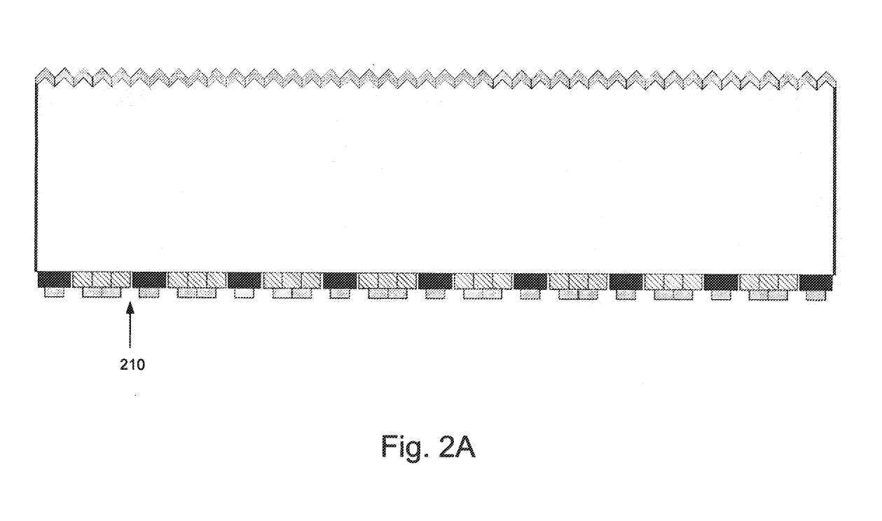

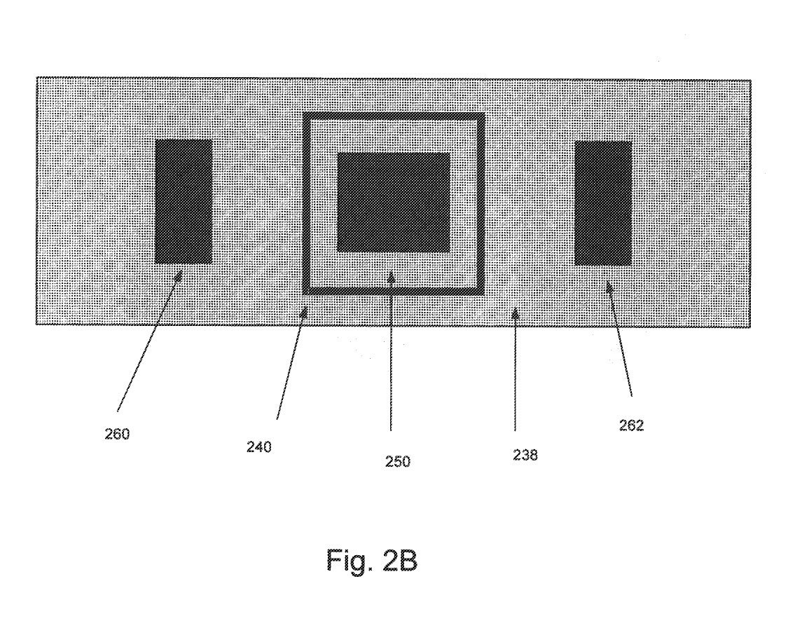

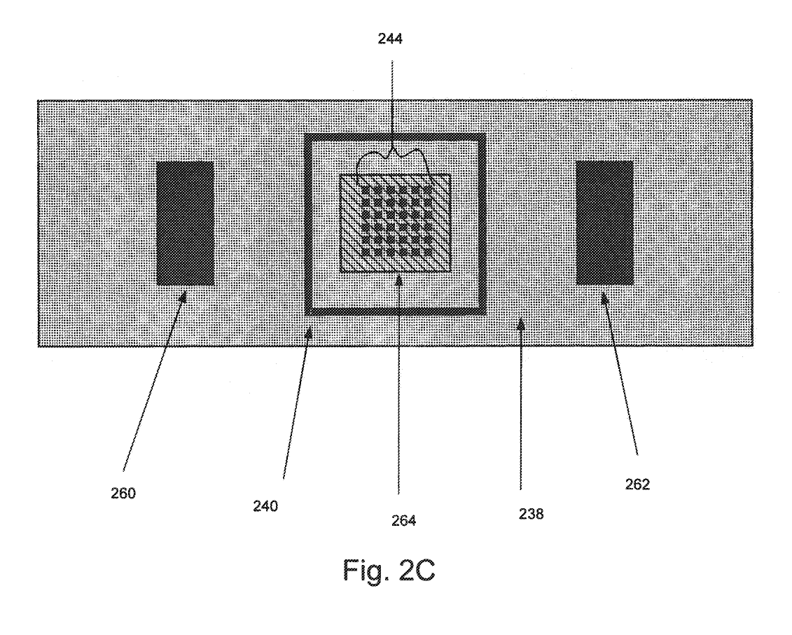

Contacts may be formed in a variety of configurations. Referring to FIGS. 2A and 2B, side and bottom views, respectively, are illustrated according to one embodiment. A region of material 210 is removed from the rear or bottom surface of the cell (FIG. 2A). To form this area or isolation, a ring of material 240 (FIG. 2B) is removed from the cell. The material removed includes a region of silicon on the cell. Removing this material isolates the connection of the bulk material and the emitter region. The region may be removed by any suitable means, such as with limitation by using a focused laser, by etching, and the like. A paste 250, for example a paste containing some conductive material such as silver and also containing a penetrating material such as aluminum, is printed in dots or bars or otherwise applied to the rear of the cell in a region inside the ring 240 on the back side of the cell and is then dried. A second paste 260 and 262 containing a conductive material such as silver and optionally an opposite doping material of the same polarity as the emitter region such as phosphorus is printed in dots or bars or otherwise applied in regions nearby and/or adjacent to the first paste 250, then dried. The cell with the two pastes is then fired at an elevated temperature. The first paste 250 penetrates the emitter region and the paste effectively contacts the bulk of the silicon 238.

In some embodiments, a photovoltaic cell is provided with a wrapped emitter configuration as shown in FIG. 2C. In this embodiment, a ring of material 240 is removed from the cell, for example using a focused laser. Additional contact regions or pits 244 are ablated, for example using the same laser system. The material removed includes the emitter region underneath. Removing this material isolates the connection of the bulk material and the emitter region. A paste 260, 262, and 264 containing a conductive material such as silver is printed in dots or bars or otherwise applied in regions over the contact pits 244 and over adjacent regions outside the ring over the emitter region, then dried. The cell with pastes is then fired at an elevated temperature. The paste 260 and 262 penetrates the emitter region and the paste in the pit region 244 effectively contacts the bulk of the silicon 238.

In some embodiments, wrapped emitter cells use an alternative contact approach, as shown in FIG. 2D. An area of material 266 is removed from the cell, for example using a focused laser or a tool which removes material by sandblasting and the like. The material removed includes the emitter region underneath. Removing this material isolates the connection of the bulk material and the emitter region. A paste 260, 262, and 264 containing a conductive material such as silver is printed in dots or bars or otherwise applied in regions inside the area 266 and over adjacent regions outside the area 266 over the emitter region, then dried. The cell with pastes is then fired at an elevated temperature. The paste 260 and 262 penetrates the emitter region and the paste in the ablated region 266 effectively contacts the bulk of the silicon 238. In another embodiment, the paste 264 contains substantially aluminum or similar dopant. In another embodiment, the paste 264 is comprised of a first layer of paste containing substantially aluminum or similar dopant, with another paste containing substantially silver printed over the first paste.

In these embodiments, the process of removing material for purposes of isolating regions or making contacts can be accomplished by several methods. A focused laser beam steered by various optics is one example. Sandblasting with an abrasive material is another. Using a screen printed diffusion isolation paste, which prevents spreading or diffusion of dopants is another method suitable according to embodiments of the present invention. In another embodiment a paste containing silicon etchant such as nitric acid and ascetic acid may be used to etch the silicon. The pastes are applied by screen printing and then allowed to etch through the desired layers of material, for example the emitter doped region.

In one embodiment, the area to be removed is masked off with a masking material, such as a screen printed polymer and the like. The cell assembly is placed in a wet chemical etch material bath such as HF to remove the nitride ARC, then subsequently a silicon etchant such as HNA (a mixture of HF, nitric acid, and acetic acid) is used to remove the emitter region. Alternately, etching can be accomplished by reactive ion etch processes utilizing gases such as sulfur hexafluoride and the like.

The bulk contact materials used to form the contacts according to some embodiments are comprised of a single material, such as a paste containing substantially aluminum. Alternatively, the contact material is comprised of two or more layers of materials, the first containing a paste of substantially aluminum, and the second overlaying paste of substantially silver, to provide a solderable contact. In embodiments where the polarity of the bulk and emitter dopants are reversed, the contact materials also are reversed in their type.

In some embodiments, the contacts are formed by plating conductive materials to the contact regions. For example, electroless nickel can be plated on to highly doped silicon regions for metal contacts. In various embodiments, a resist masking material is screen printed over areas in which no plating is desired. Electroless or electroplated materials such as nickel or copper are then deposited in the areas not masked. The deposited materials may also be comprised of multiple layers of materials, such as nickel followed by copper.

In alternate embodiments, a masking material such as a lift off resist is applied over regions to be protected, and a single or multi-layer stack of materials are sputtered or otherwise deposited over the contact areas and mask material. The lift-off resist mask material is then removed. Although in some of the figures the regions of opposite doping are shown with a space, in alternate embodiments these regions may be immediately adjacent to each other. Those of skill in the art will recognize that other orientations or configurations may be used within the spirit, scope and teachings of embodiments of the present invention.

### Fabrication of Photovoltaic Cells

Fabrication of photovoltaic cells according to various embodiments of the present invention are now described in detail. A process for making such a cell, in this case a rectangular cell, in accordance with one embodiment starts with a wafer of <1,1,0> oriented silicon. According to various embodiments, the silicon is one or more of: of high purity; doped with an N- or P-type dopant; undoped; in the form of a wafer that is approximately 1 to 2 mm thick; and in the form of a wafer that is 100 mm or more (e.g., 150 mm) in diameter. In various embodiments, the silicon boule has a wafer flat, cut with a relatively high degree of precision. The specification for the cutting is typically within ±0.5°, but is optionally cut to within ±0.1° in accordance with the various embodiments. Since these wafers are going to be aligned and etched with respect to the crystal orientation, small amounts of deviation can end up thinning one side of the cell as the cell is being formed, such that a tight tolerance forms cells more precisely. In some embodiments, the wafers are cleaned using an appropriate process, such as a piranha cleaning process. In some embodiments, the wafers are polished, such as by double polishing the surfaces and optionally rounding the edges.

In one embodiment, a silicon nitride mask layer about 2,000 Å thick is deposited on all sides of the wafer. In an alternate embodiment, a layer of thermally grown oxide about 1u is formed over the entire wafer, followed by deposition of a silicon nitride layer of 1000 A. The wafer is then optionally prepared for photoresist deposition, such as by applying Hexamethyldisilazane (HMDS) primer to serve as an adhesion promoter for photoresist. According to various embodiments, the photoresist is spun on the front and back side of the wafer, applying the photoresist to the front and back simultaneously or at different times.

In some embodiments, a photosensitive polymer such as Protek PSB-23 is applied to the surfaces of the wafer. This polymer also uses a primer coating prior to application of the photosensitive polymer.

In some embodiments, a jig is used that has a large plate with three pins. A mask plate consisting of a pattern of slots is put on the jig, with the mask plate also having three pins which align the wafer flat on two of the pins and the wafer edge on the third pin, thereby aligning the wafer to the mask. Another mask plate can be placed on top, which sits on the pins of the main piece. The jig device then has a front mask and a back mask that come down on the top and bottom of the wafer such that both sides can be exposed simultaneously. Preferably, but not necessarily, the front and back of the wafer is exposed at the same time, so that after baking, the wafer is ready to etch. In some embodiments, the photosensitive material is exposed and developed on one side at a time.

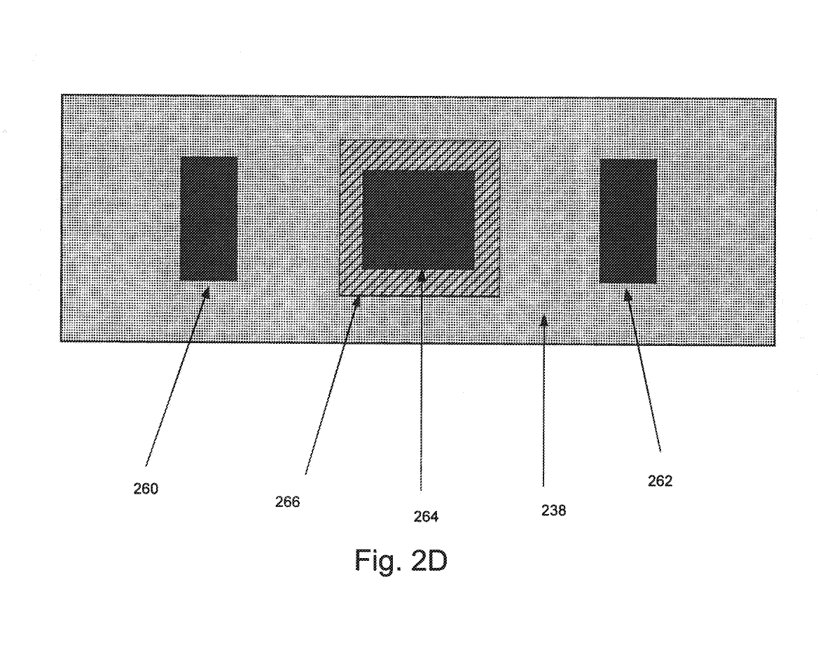

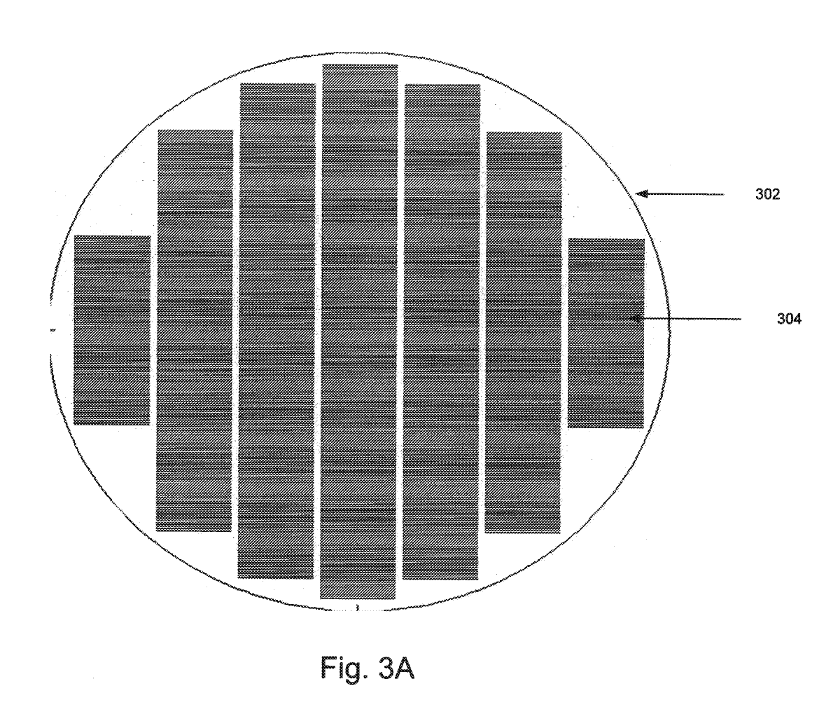

Such a process can be used to form a set of parallel slots on the front and back of the wafer, although some embodiments utilize only slots on the front or back of the wafer. An example of a pattern region for the slots in accordance with one embodiment is shown in FIG. 3A. Slots are formed such that elongated columns of silicon are created in the patterned region 304. As can be seen in the figure, the slots are not formed from a rectangular region, but from a pattern region 304 shaped to utilize substantially all of the material of the workpiece 302 (such as a wafer or an ingot). Using a rectangular pattern with a round workpiece, for example, results in a substantial amount of the material of the workpiece being wasted. Using a pattern that substantially matches the size and the shape of the workpiece allows for long, thin slots to be formed that run approximately the width of the workpiece, so that almost all the material of the workpiece is used. This also results in a substantial increase in the active surface area obtained from a wafer. In the example of FIG. 3A, where the workpiece is a silicon wafer having a circular shape, the edge of the pattern region for the slots is substantially circular, corresponding to an outer edge of the workpiece. This correspondence allows a majority of the material of the workpiece to be used in forming the slots (and the resultant strips of material). In one embodiment, at least 80% of the material of the workpiece is used in the patterning region.

In the pattern region 304, the pattern for the individual parallel slots can be formed as shown in the workpiece 302. As can be seen, the pattern for groups of adjacent slots extend substantially to the edge of the workpiece. The slots in this example have 80 μm nominal spacing, with 15 μm openings. Columns of patterned wafer material will be cut from the wafer prior to etching, see cut marks 308 in FIG. 3B. The columns of patterned wafer material will have the unpatterned material also cut from columns see cuts 310 and 312, such that what remains is a rectangular block of material with a slot pattern running the width of the column. After etching of the blocks, the resulting bars then typically are on the order of about 50 μm or less in thickness after etching through the blocks. The use of blocks of a relatively short width reduces the need for the tolerance of the long blocks to be accurately aligned to the crystal orientation.

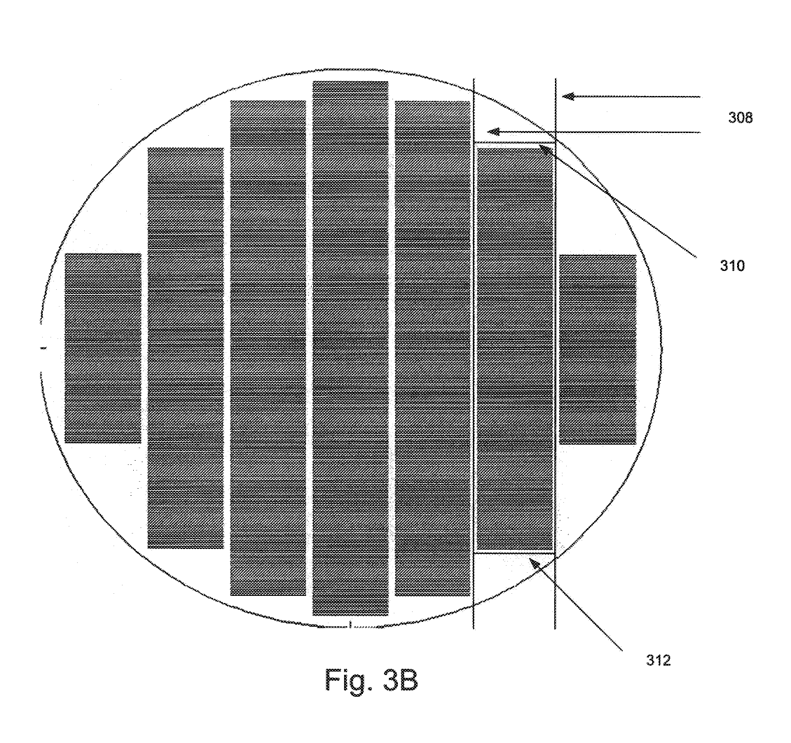

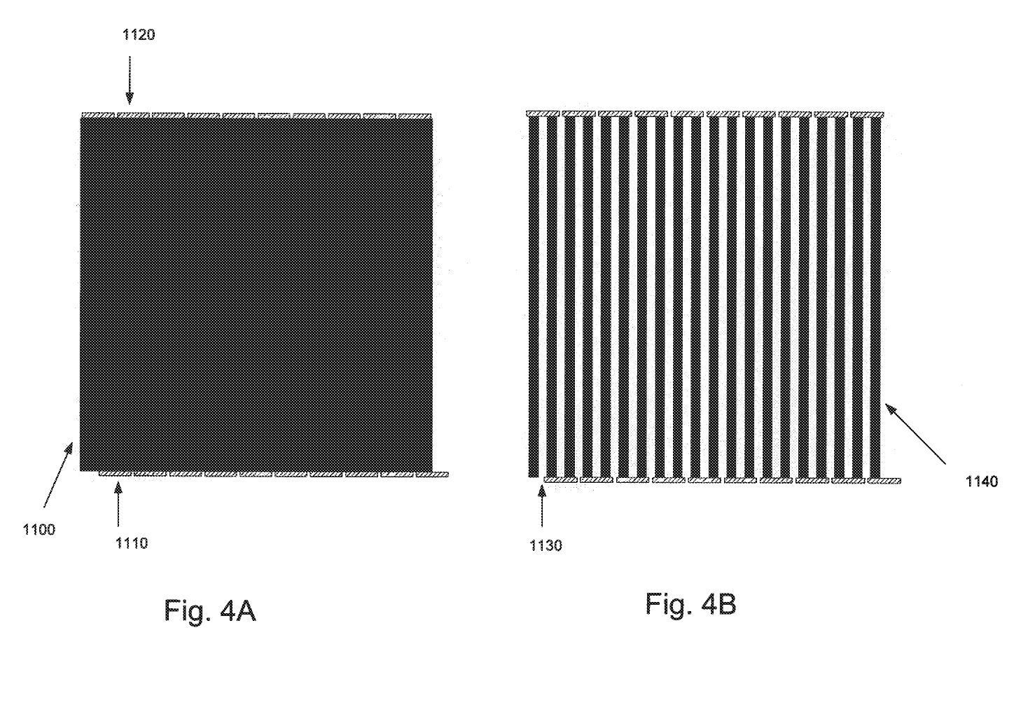

The patterned region uses an alternating structure for the front and the back sides. The one side slots 1110 are positioned to be in the middle of the other side slots 1120 of FIGS. 4A and 4B.

After the front and back of the device are patterned, and the patterned resist is developed and baked by an appropriate developing and baking procedure, the exposed nitride layer or nitride/oxide layer can be etched down to the silicon. The resist is then removed. The front and back patterns are substantially identical and aligned such that the front and back slots line up as discussed above. In an alternate embodiment, a silicon dioxide layer is deposited over the nitride. The oxide layer is etched with a hydrofluoric acid wet etch, then the nitride layer uses the oxide layer as a mask and is then wet etched using a hot phosphoric acid.

In an alternate embodiment such as using a alkaline resistant photopolymer, after developing and baking the photopolymer, and cutting the wafer into blocks, the silicon is ready for the deep etch. This embodiment has the advantage of not requiring the etch of the nitride or nitride/oxide mask layers, and removal of the resist material.

In an alternate embodiment, a silicon dioxide layer is deposited over the silicon, such as a grown thermal oxide. Then a nitride layer is deposited. An optional 3^{rd} oxide layer may then be deposited. The initial oxide layer typically has an opposite film stress as the nitride layer, which reduces or prevents cracking of the mask.

The device then can undergo a deep etch in a wet bath, such as an anisotropic wet etching bath using a solution of 40% in weight of potassium hydroxide (KOH) in water at 80 C. In an alternate embodiment an alkaline mixture of TMAH or tetra-methyl ammonium hydroxide and water is used. Optionally isopropyl alcohol may be added to improve the surface quality of the silicon surfaces. This etch proceeds all the way through the block of silicon to the mask material on the other side of the block.

During the slot etch, hydrogen bubbles form in the slots. These can tend to slow the etch process, or cause the etching to proceed unevenly, particularly as the slots become deeper. By agitating the wafers in the etch bath, the bubbles can be removed at a rate more often than that which would occur without agitation, and provide a more uniform deep etch.

The etching process (which can include any of a number of other etching processes than a KOH wet etch) creates a number of slots through the wafer or blocks. An advantage to using substantially square cells, instead of elongated strips as in the prior art, is that virtually the entire wafer can be used. When using long strips that must all be of the same size, the useable area of the wafer is effectively a square, which means that about half of a round silicon wafer is wasted. When using rectangular cells, the micro-tiles etched into the wafer (that are subsequently are diced into individual cells) can be of varying length. The resulting cells can be small, such as on the order of about 40 mm or less, and in some embodiments on the order of 6 mm or less in length, and can have an edge ratio of 20:1 or less. Using the assembly method as described herein, however, a rapid assembly of modules of such cells can be obtained that is both economical and practical.

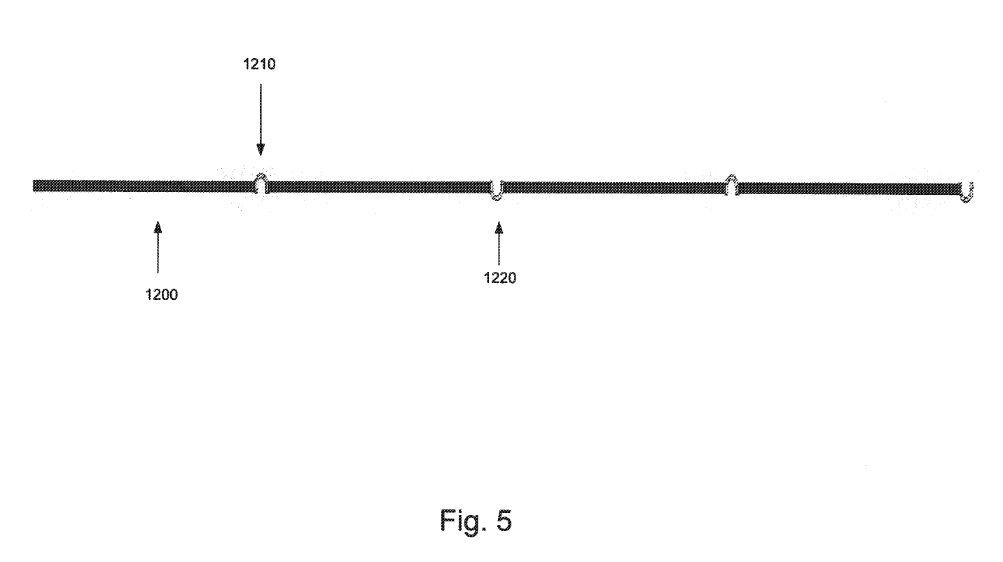

After etching, the block or column of silicon material will contain thin micro-tiles of silicon 1140 as shown in FIG. 4B. The blocks can then be unfolded into long strips of micro-tiles 1200 held together by hinges 1210 and 1220 as show in FIG. 5 and described in more detail below.

After unfolding the strips of micro-tiles, in one embodiment the strips are placed on an adhesive coated substrate such as a silicon substrate used as a temporary handle substrate.

In an alternate embodiment the micro-tiles are formed in the columns or blocks shown in FIG. 3B while still part of the wafer. The pattern of FIG. 3B is used on both sides of the wafer to form a mask for etching. The wafer is etched in a suitable etchant as described previously, such that the slots are formed through the wafer. An adhesive backed material such as adhesive tape is applied to the front and back of the wafer. A laser or other similar cutting device then cuts an alternating pattern, similar to that shown in FIG. 4B in the tape on both sides of the wafer. Optionally the wafer is attached to a mounting substrate with thermal release tape or similar tape. The wafer is then cut with a dicing tool or laser at locations 308 as shown in FIG. 3B. Optionally the blocks of material cut from the wafer are then released from the mounting substrate by heating or the appropriate method needed by the release tape. The blocks can then be unfolded into long strips of micro-tiles 1200 held together by hinges 1210 and 1220 as show in FIG. 5.

In an alternate embodiment, a flexible material is applied to the front and back of the wafer such that it adheres to the wafer. The flexible material is a photosensitive material such that when exposed to a pattern and developed, regions of the flexible material will be removed. The pattern of the removed region is shown in the cross section of FIG. 4B.

The wafer is then diced into blocks, which remove the dividing bars between regions of the wafer. The blocks of micro-tiles are now interconnected by the flexible material which serves as a hinge between micro-tiles. The block of micro-tiles is then unfolded and formed into a long strip of micro-tiles with hinges between the micro-tiles, as shown in FIG. 5.

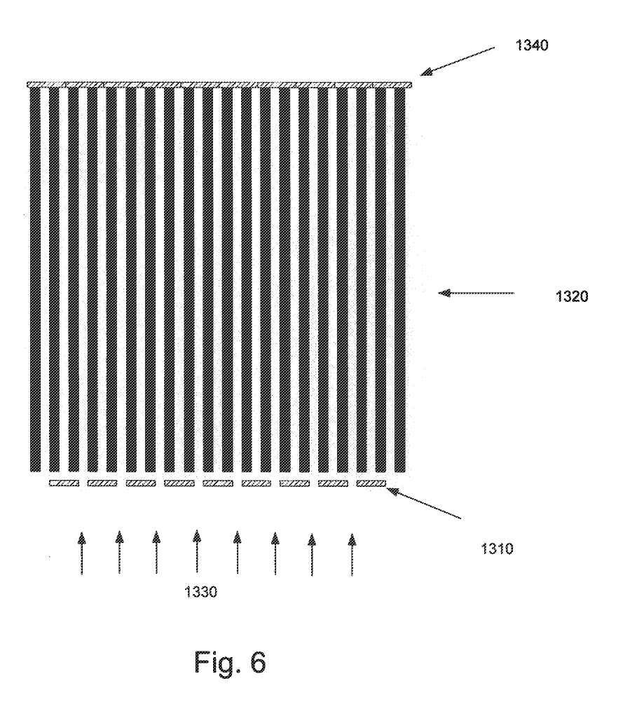

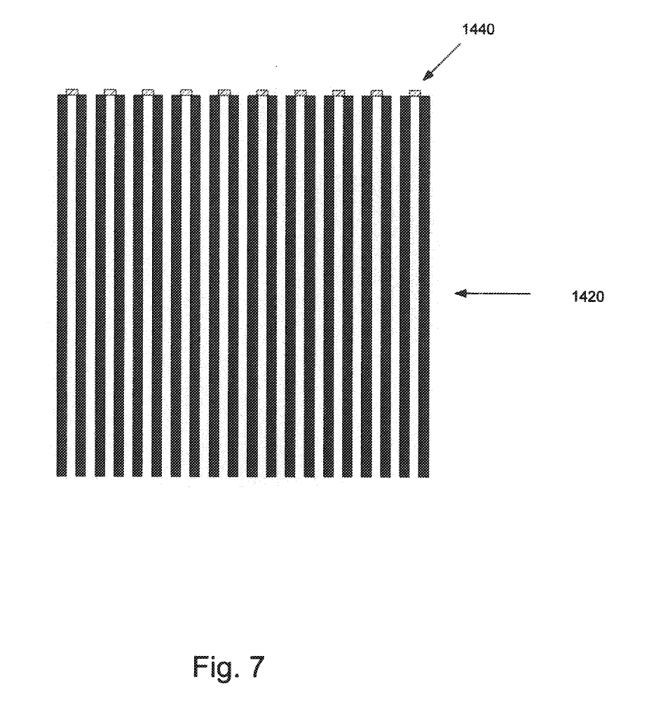

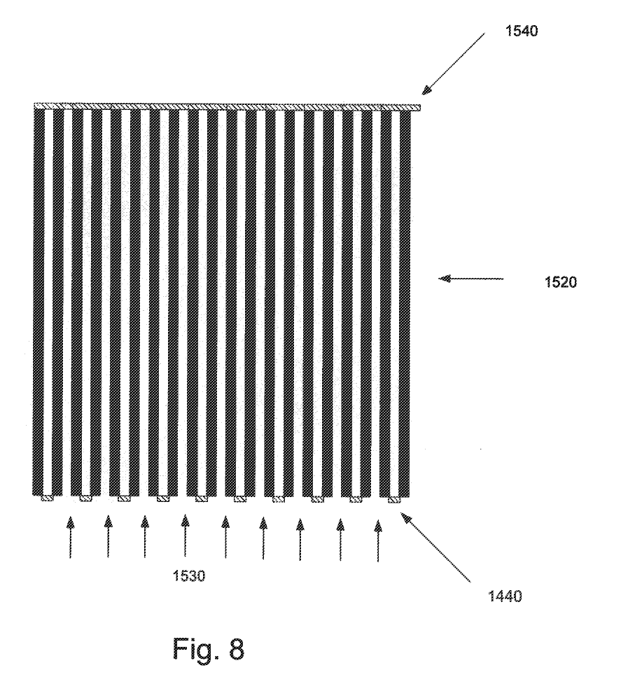

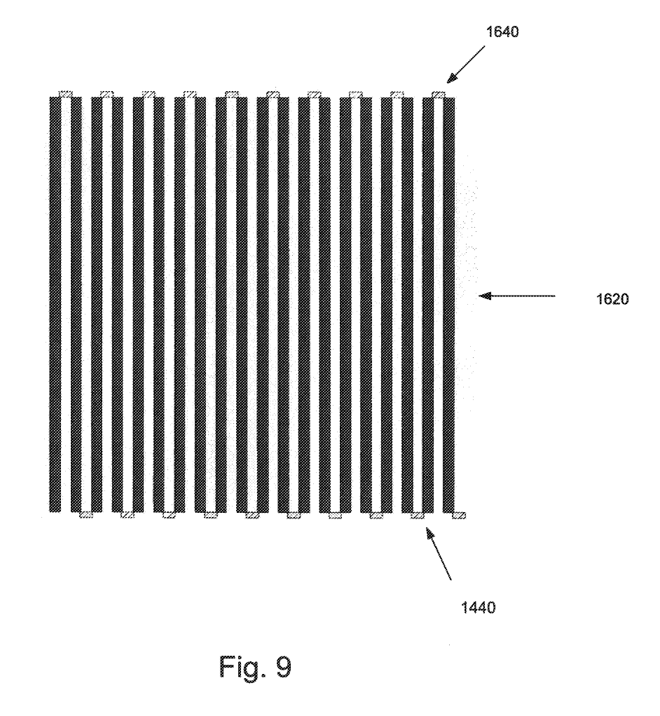

Formation of the hinge according to an alternate embodiment is illustrated with reference to FIG. 6 to FIG. 9 which shows an exemplary process sequence. A photosensitive material 1340 is applied to one side of a wafer, and a mask 1310 is placed on the opposite side of the wafer. A light source 1330 is applied that projects light through the openings in the mask 1310, and through the slots in the wafer, such that every other slot opening receives light, exposing the photosensitive material 1340, as shown in FIG. 6. After developing, every other slot is now connected by the hinge material 1440 as shown in FIG. 7. A second photosensitive material 1540 is applied on the opposite side of the wafer from the side with hinge material 1440 as in FIG. 8. A light source 1530 is applied that projects light such that every other slot is masked by the existing hinge material 1440, as in FIG. 8. After developing the hinge material 1540, a second set of hinges 1640 are formed in an alternating arrangement, as shown in FIG. 9. When the blocks are removed from the wafer, the series of cells can be unfolded as in FIG. 5.

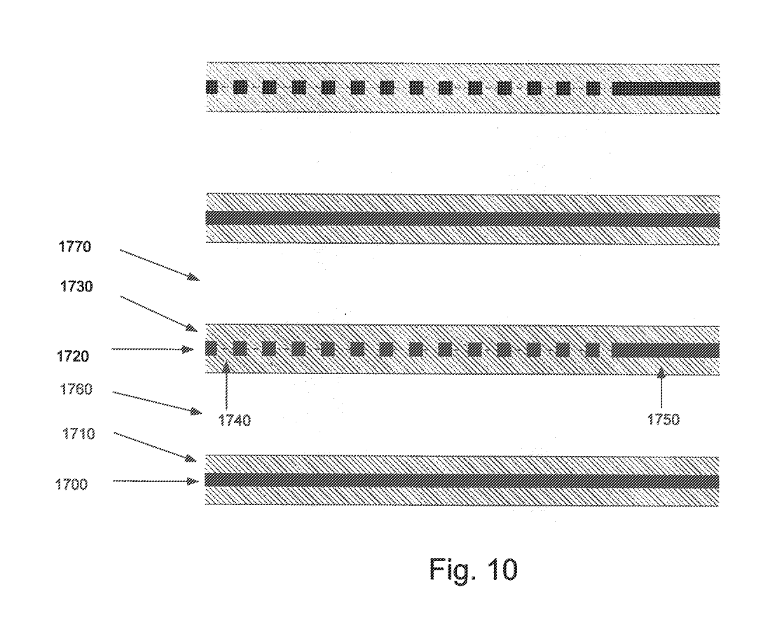

In an alternate embodiment, a mask pattern with a web pattern is used to form the hinge such as is illustrated in FIG. 10. The pattern is identical on the opposite side of the wafer, but offset such that a slot pattern 1700 is aligned with a web pattern 1720. Etching proceeds from both sides of the wafer with etched slots that meet at a point inside the wafer. Micro-tiles 1760 and 1770 are formed between the slots. An advantage of this method is etch time is reduced up to ½ the total time, and the amount of silicon etched is reduced. The web pattern 1740 then provides a platform for subsequent application of a hinging material, such as a flexible plastic. With suitable materials the mask itself may act as the hinge material. A long slot 1750 is used on either end of each micro-tile to ensure minimum waste at the ends of the micro-tiles.

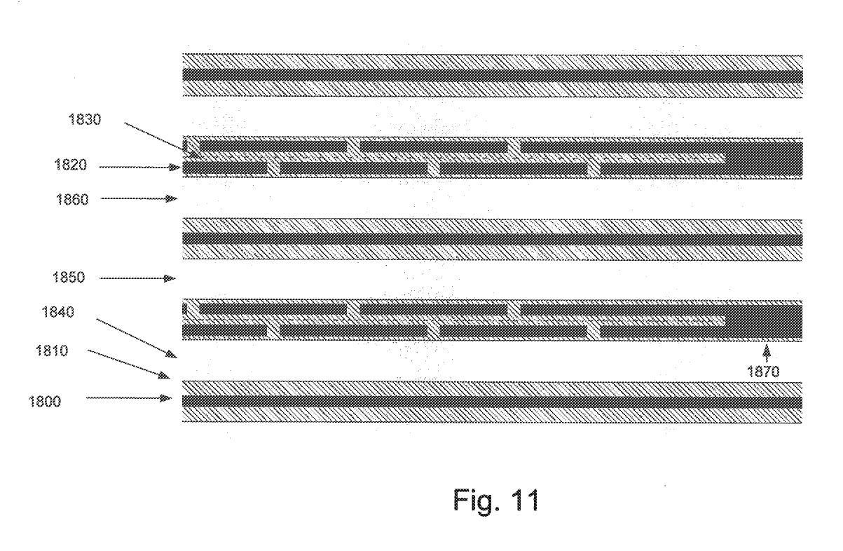

In an alternate embodiment, a mask pattern with a web pattern is used to form the hinge such as shown in FIG. 11. The pattern is identical on the opposite side of the wafer, but offset such that a slot pattern 1800 is aligned with a web pattern 1820. Etching proceeds from both sides of the wafer with etched slots that meet at a point inside the wafer. Micro-tiles 1840, 1850 and 1860 are formed between the slots. An advantage of this method is etch time is reduced up to ½ the total time, and the amount of silicon etched is reduced. The structures at 1830 form a torque bar which distributes the torsional forces when bending the micro-tiles during the unfolding process. The pattern 1830 then provides a platform for subsequent application of a hinging material, such as a flexible plastic. With suitable materials the mask itself may act as the hinge material. A long slot 1870 is used on either end of each micro-tile to ensure minimum waste at the ends of the micro-tiles.

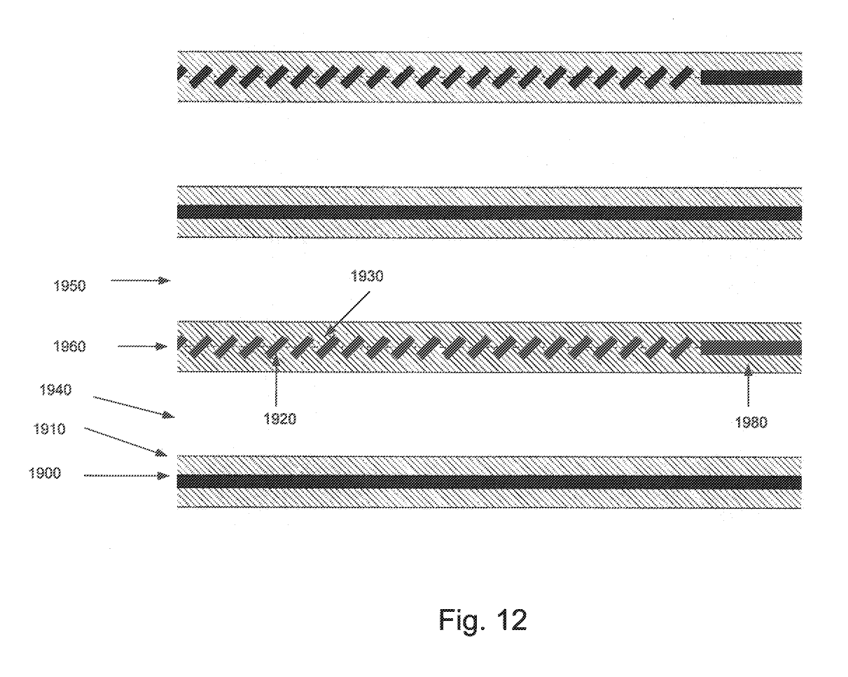

In an alternate embodiment, a mask pattern with a web pattern is used to form the hinge as shown in FIG. 12. The pattern is identical on the opposite side of the wafer, but offset such that a slot pattern 1900 is aligned with a web pattern 1760. Etching proceeds from both sides of the wafer with etched slots that meet at a point inside the wafer. Micro-tiles 1940 and 1950 are formed between the slots. An advantage of this method is etch time is reduced up to ½ the total time, and the amount of silicon etched is reduced. The web pattern 1930 then provides a platform for subsequent application of a hinging material, such as a flexible plastic. With suitable materials the mask itself may act as the hinge material. A long slot 1980 is used on either end of each micro-tile to ensure minimum waste at the ends of the micro-tiles.

After placing the micro-tiles on the temporary substrate, it can be desirable in at least some embodiments to texture one or both of the sides of the micro-tiles. In one approach, a reactive ion etch using SF₆ or similar silicon etchant is used. Isotropic etching of the silicon creates cavities in silicon, thus texturing the silicon surface. Texturing can be beneficial in that texturing tends to bend the incident light rays so the rays take a longer path through the cell, which can improve the efficiencies of the resultant photovoltaic cells. Texturing can add an additional cost however; which can be balanced with the amount of improvement obtained.

After texturing, in some embodiments it may be desirable to deposit an anti-reflection coating (ARC). In one example an ARC may be deposited by screen printing a material which after firing leaves a thin layer of titanium oxide. In another embodiment an ARC is a sputtered layer of silicon nitride. Silicon nitride may be deposited by a number of means such as low-pressure chemical vapor deposition (LPCVD) and the like.

### Photovoltaic Device Assembly Process

Once the individual micro-tiles are formed, additional process steps can be used to form a solar panel or other photovoltaic device using the cells. According to various embodiments, a photovoltaic device assembly process comprises one or more of a cell organization process, a group transfer process, a sub-module assembly process, and a panel assembly process. The cell organization process arranges cells in groups on an assembly fixture so that multiple cells are enabled to be manipulated as a unit, increasing efficiency. The group transfer process transfers groups of the cells from the assembly fixture to one or more substrates, optionally via intermediate transfer points. The sub-module assembly process assembles a photovoltaic sub-module using the substrates. The panel assembly process assembles a photovoltaic device from multiple photovoltaic sub-modules.

In some embodiments the photovoltaic device assembly process comprises one or more of a cell organization process, a group transfer process, and a panel assembly process. The cell organization process arranges cells in groups on an assembly fixture so that multiple cells are enabled to be manipulated as a unit, increasing efficiency. The group transfer process transfers groups of the cells from the assembly fixture to one or more substrates, optionally via intermediate transfer points. The panel assembly process assembles a photovoltaic device from the intermediate substrates. Each step is described in more detail below.

### Cell Organization and Group Transfer Process

In one embodiment, after through block etching, the block of micro-tiles is unfolded and formed into a long strip of micro-tiles with hinges between the micro-tiles, as shown in FIG. 5. The strips of micro-tiles are adhered to a temporary substrate such as a silicon plate.

As described above and illustrated with reference to FIGS. 1A to 2D, dopants and/or contacts may be formed on some or all of the micro-tiles. Of particular advantage methods of the present invention enable significant flexibility in the manufacturing process. For example, selective doping may be employed meaning that dopants of varying composition and/or concentration may be applied independently to different regions of the micro-tiles thus providing photovoltaic cells with selective doping profiles. A series of bars or dots of a diffusion barrier material are screen printed on the collection of micro-tiles and dried. A series of bars or dots of a dopant material opposite of the bulk material are screen printed in the region outside of the barrier material including the sides of the micro-tiles and dried. The micro-tiles, barrier material and dopant are then fired at a temperature sufficient to drive in the dopant.

This elevated temperature also removes the adhesive binding the micro-tiles to the temporary substrate as well as the polymer hinges holding the micro-tiles together.

An adhesive is applied to a second temporary substrate such as a silicon plate, and the micro-tiles are placed against this second plate such that the micro-tiles transfer to the second plate.

An optional texturing step may be applied, such as exposure to SF₆ to etch cavities in the micro-tiles.

A second dopant of similar type to the first dopant paste and opposite to the bulk dopant is applied over the entire micro-tile surface as well as the sides of the micro-tiles. The dopant may be fired and diffused into the front surface of the micro-tile, or optionally the firing may be processed after the application of the anti-reflection coating paste.

The use of a second dopant paste enables the doping of the front surface of the micro-tile to be performed with different parameters than the rear side. On the front side it is desirable to have the doping be as light as possible to enable extraction of more blue photons, whereas on the rear side high conductivity is preferred.

In one embodiment, the micro-tiles are transferred in a group process to a substrate, such as borosilicate plate or other clear substrate substantially covered with an adhesive. This places the front side of the micro-tile against the borosilicate plate.

In one embodiment, a frit paste consisting of one or more glass frit powders is applied over the surface of the micro-tiles. In one embodiment, a squeegee is drawn across the surface of the micro-tiles applied such that the frit paste is removed from the surface of the micro-tiles, but remains in the spaces between the micro-tiles. In one embodiment, the assembly is then fired at an elevated temperature to bond the micro-tiles to the borosilicate or similar glass. In another embodiment the firing process is deferred to a later step.

In some embodiments, it may be desired not to bond the array of micro-tiles to glass, but instead arrange the array of micro-tiles to be connected together such that the array of cells acts as a sheet of micro-tiles substantially the thickness of the micro-tiles. In one embodiment, the micro-tiles are transferred to an adhesive coated substrate such as silicon. The substrate plus micro-tiles are then bathed in a powder of silica glass, or a similar high temperature glass powder. In some embodiments, after the application of the layer of adhesive, the substrate is bathed in the silica or similar glass powder. Then a second layer of adhesive is applied, and the micro-tiles transferred to the substrate over the adhesive.

In some embodiments wherein it is desired to have a thin sheet of micro-tiles, a frit glass paste mixture is then applied between the rows of micro-tiles to fill all or part of the gap between the micro-tiles.

In some embodiments wherein it is desired to have a thin sheet of micro-tiles, one of the conductors, such as the emitter conductor paste, is applied in part or all of the region between the micro-tiles.

In these embodiments, the frit glass or conductor glass is applied to create a bridge or connector between the micro-tiles. After a subsequent firing operation, the frit paste or conductor paste will harden. The silica powder or similar glass will not harden at the firing temperatures, and will act as a release agent, and allow the array of micro-tiles to float free of the substrate, but be connected together everywhere the frit glass or conductor bridges sets of micro-tiles.

A set of contacts using a screen printed silver paste is applied either in dots or bars over the emitter regions of the rear side of the micro-tiles. In some embodiments the bars connect multiple cells together. The paste is then dried. A second set of contacts applied as bars or dots using a screen printed paste containing aluminum and silver and optionally boron is applied over the regions protected by the diffusion barrier. In some embodiments these second bars connect multiple cells together.

In some embodiments where the cells have solely rear contacts, both contacts may be printed in this step. In other embodiments where the cells have rear contacts, one set of contacts is printed in this step.

In some embodiments, the cells (with printed contacts) are then fired. In various embodiments, all of the contacts are fired simultaneously.

In various embodiments, to test the cells, an array of conductive probes is brought into contact with the contacts of the cells. In some embodiments, a light source is used to illuminate the cells under test, and the cells are placed under load to evaluate a power output of the cells under with known illumination, such as an approximate solar illumination. In further embodiments, a map is made in the controlling computer of output of the cells.

In some embodiments, cells that are identified as outside of a desired range of output are electrically removed from the system by using a laser to cut out regions which electrically isolate the contacts from the interconnect.

### Sub-Module Assembly Process

In some embodiments of the sub-module assembly process, arrays of cells are transferred to a substrate, such as by a group transfer process, and the cells are permanently fixed to the substrate and electrically interconnected to form a sub-module. According to various embodiments, a size of the sub-modules is selected for compliance with standards and/or convenience and/or ease of handling and/or ease of assembly (at the sub-module and/or at the panel level), such as 4″×4″ or 8″×8″ sub-modules.

In some embodiments, the cells of one of the sub-modules are electrically connected partly in series and partly in parallel, such as by connecting a subset of the cells in parallel, and connecting a plurality of the subsets in series. In various embodiments, a combination of series and parallel connections of the cells is used to create any desired voltage. In a first example, all of the cells of a first one of the sub-modules are connected in parallel, producing roughly 0.5V. In a second example, a second one of the sub-modules is divided into 4 sections, each section being a subset of the cells connected in parallel and providing 0.5v output. By connecting the four sections placed in series, the second sub-module produces 2V.

In the third example, a row of cells is connected in series, then these rows are connected in parallel. For example, a series of 44 cells are connected in series to form approximately 22V, then 16 of these rows are connected in parallel.

In some embodiments, an arrangement of cells on the sub-module takes advantage of the property of manufacturing wherein some cells will have a certain output, and other cells will have a different output.

In some embodiments, cells with a lower current output will be grouped and wired in parallel so as to create a group with a total current output of X. A second set of cells with a higher current output will have a fewer number of cells wired in parallel such that the sum of the current is also substantially X. This second set of cells will be connected in series with the first set. Additional groups of cells with higher current outputs and fewer cells, but each having substantially X current output as a group, can be connected in series with the other sets to form a sub-module with a substantially X current output, and the sum of the groups cell voltages as the voltage output.

In some embodiments, a substrate, such as FR4 glass as is commonly used in printed circuit boards, is used as a carrier for the cells. A single layer of copper is patterned to form an interconnect to connect the cells (in series and/or in parallel and/or in any combination of series and parallel) as desired on the substrate. In various embodiments, additional patterns of masking material are optionally used to prevent shorting. A pattern of solder, such as a tin/silver paste, is optionally screen printed to the copper clad substrate. The cells are placed on the substrate, such as by transferring one or more arrays of cells to the substrate using a group transfer process. In various embodiments, such as where the cells have at least some connections on a front side of the cells, additional interconnect is applied on top of the cells to connect the front-side connections. Then, the substrate with cells and the interconnect(s) is heated to melt the solder and connect the cells to the substrate.

In some embodiments, the substrate is made of an inexpensive material, such as plastic (for example acrylic). An interconnect pattern is printed on the plastic using a conductive thermoplastic or epoxy paste, such as a silver-containing epoxy paste. While the conductor is wet, the cells are pressed into the conductor (such as by using a group transfer process), then released. The assembly optionally has top conductors added. Then, the assembly is cured to solidify the conductive paste.

In some embodiments, such as for substantially parallel groupings of the cells, a conductive substrate, such as stainless steel, is used. The conductive substrate optionally includes insulators that mask off the regions that are not desired to be conductive. In various embodiments, the conductive substrate is used in a case where back sides of the cells are all connected in parallel.

In some embodiments, subsets of the cells are connected in series, then the subsets are connected in parallel to form higher voltage sub-modules. An advantage to connecting serial subsets in parallel is that loss of one of the cells can result in a shorted connection. In a first example, if there is a series-connected subset of cells, such as twenty cells at 0.5V each forming a 10V string of the cells, a lost one of the cells results in voltage of the string dropping to 9.5V. If, however, the string is a first string and is connected in parallel with a second, similar string, then the average output of the strings will be somewhere between 10V and 9.5V. In a second example where a sub-module of the cells is connected solely in parallel and produces 0.5V, a shorted connection for one of the cell can result in pulling the entire sub-module down to almost no output. “Serial-parallel” sub-modules thus produce output even in an event of a lost one of the cells.

In some embodiments, subsets of the cells are connected in parallel, with one or more cells wired with its two connections in reverse of the other cells. These reverse cells act as bypass diodes. In the event of partial shading of the subset of cells, such that its output falls below adjacent subsets of cells, the bypass diode will forward bias and allow current to bypass the subset of cells. In some embodiments, every submodule has one or more cells configured as bypass diodes.

Once diced into individual square or rectangular cells and assembled into one or more sub-modules, cells made from a wafer such as the example wafer presented above, with a typical 20% efficiency, can produce over 67 watts of power from full solar irradiation. A similar volume of single crystal silicon material cut into conventional solar cell wafers with the same efficiency from 5 wafers, for example, would produce about 17 watts. In some embodiments this results in up to almost a 4× improvement in power from the same amount of silicon.

### Panel Assembly Process

In some embodiments, a panel assembly process assembles a photovoltaic panel from a plurality of sub-modules, the sub-modules produced by a sub-module assembly process. According to various embodiments, the panel assembly process comprises one or more of: orienting the sub-modules; mounting the sub-modules on a carrier; electrically interconnecting the sub-modules; conformably coating the sub-modules and/or the sub-module/carrier combination; and encasing the carrier in a protective cover.

### Other Crystalline Materials

Although many of the examples provided herein are described with respect to silicon of a certain orientation, it should be understood that there are a number of other materials and orientations that can be used as would be apparent to one of ordinary skill in the art in light of the teachings and suggestions contained herein. For example, cells may be fabricated from other suitable materials such as germanium. Using such cells, a much higher efficiency multi junction cell may be formed by depositing many layers of different materials. One advantage of such an approach is the reduced amount of germanium required, which results in lower cost.

### Optical Concentrator

An additional benefit can be obtained when photovoltaic cells as discussed above are configured to work with an optical concentrator as known in the art. For example, a holographic pattern that functions as a multitude of lenses can be is stamped into the side of a clear plastic substrate, opposite a column of square or rectangular cells. Such a concentrator can focus solar radiation onto the array of columns of cells. Instead of using an array to cover a full area, a device can include only columns or linear arrays of cells. This can reduce the number of cells needed and therefore the cost of the device. In this example one quarter the number of cells are needed for the same area of a system without the concentrator cells. The concentrator can focus solar radiation over a range of angles that the sun may have relative to the module, unlike conventional concentrators which may use Fresnel lenses. The concentrator itself can introduces losses, but for the example shown, with a 75% efficiency of the concentrator, the system can have an overall utilization of silicon that is 12× lower for the same power output than conventional silicon cells.

In some embodiments, photovoltaic materials which exhibit crystal structures which have etchants capable of preferentially etching at right angles to the surface of the material can be used. In some embodiments, dry etching processes such as a Bosch silicon etch process can be used to cut the wafer into segments. In some embodiments, a laser can be used to cut the photovoltaic material into segments. In some embodiments, a narrow jet of high pressure liquid can be used to cut the photovoltaic material into segments.

### Conversion of Light to Optimal Bands

It is desired to improve the efficiency of silicon as a photovoltaic material. It is noted that the conversion of the solar spectra has a maxima in the red and infra-red regions, and response falls off as the spectra decreases in wavelength. In prior art techniques a number of materials such as fluorescent paints tend to absorb shorter wavelengths of light, then re-emit their energy at longer wavelengths. A drawback of this process is that the fluorescent material itself may occlude the passing of light to a silicon cell. To address this limitation, embodiments of the present invention include application of small particles of fluorescent material such that their size allows longer wavelengths of light to pass through them while absorbing the shorter wavelengths and re-emitting these photons as longer wavelength light. The particle size thus acts as a low pass filter, allowing longer wavelength light, either directly from solar illumination or from the re-emission of the fluorescent material to pass to the silicon underneath. Therefore the fluorescent material may be applied directly over the silicon photovoltaic devices, ideally as a simple painting procedure.

It should be recognized that a number of variations of the above-identified embodiments will be obvious to one of ordinary skill in the art in view of the foregoing description. Accordingly, the invention is not to be limited by those specific embodiments and methods of the present invention shown and described herein. Rather, the scope of the invention is to be defined by the following claims and their equivalents.

What is claimed is:

1. A photovoltaic cell, comprising:
at least one silicon micro-tile having at least two oppositely doped regions forming a diode; and
a pair of contacts on a common edge of the silicon micro-tile.

2. The photovoltaic cell of claim 1, wherein the pair of contacts are on one of the top or rear edges of the silicon micro-tile and on at least one opposing side edge of the silicon micro-tile.

3. The photovoltaic cell of claim 1, wherein the pair of contacts are formed on the top and rear edges of the silicon micro-tile and on at least one opposing side edge of the silicon micro-tile.

4. The photovoltaic cell of claim 1, wherein the silicon micro-tile further includes an emitter around at least a portion of the circumference of the silicon micro-tile.

5. The photovoltaic cell of claim 1, wherein the silicon micro-tile further includes an emitter around the entire circumference of the silicon micro-tile.

6. The photovoltaic cell of claim 1, wherein the silicon micro-tile is comprised of crystalline silicon.

7. The photovoltaic cell of claim 1, wherein at least one surface of the silicon micro-tile is comprised of crystalline silicon having a crystalline orientation of <1,1,0>.

8. The photovoltaic cell of claim 1, wherein the silicon micro-tile is selectively doped.

9. The photovoltaic cell of claim 1, wherein at least one of the top, rear and opposing side edges of the silicon micro-tile exhibits an independent dopant profile.

10. A photovoltaic cell comprising: at least one elongated silicon micro-tile having at least two oppositely doped regions forming a diode, and an emitter wrapped around the substantial circumference of the silicon die.

11. A solar panel, comprising:
a plurality of rectangular photovoltaic cells, each photovoltaic cell having at least two oppositely doped regions forming a diode, each photovoltaic cell further having a pair of contacts on a common edge of the cell;
a substrate for receiving the plurality of rectangular photovoltaic cells; and
an interconnect layout electrically connecting the plurality of rectangular photovoltaic cells.

12. The solar panel of claim 11, wherein the pair of contacts on each photovoltaic cell are on one of the top or rear edges of the cell and on at least one opposing side edge of the cell.

13. The solar panel of claim 11, wherein the pair of contacts are formed on the top and rear edges of the cell and on at least one opposing side edge of the cell.

14. The solar panel of claim 11, wherein at least one of the plurality of photovoltaic cells further includes an emitter around at least a portion of the circumference of the cell.

15. The solar panel of claim 11, wherein at least one of the plurality of photovoltaic cells is comprised of crystalline silicon.

16. The solar panel of claim 11, wherein at least one of the plurality of photovoltaic cells is comprised of crystalline silicon having at least one surface with a crystalline orientation of <1,1,0>.

17. The solar panel of claim 11, wherein at least one of the plurality of photovoltaic cells are selectively doped.

18. The solar panel of claim 17 wherein the front surface of at least one of the plurality of photovoltaic cells is lightly doped and the rear surface and opposing side surfaces are heavily doped.

19. The solar panel of claim 11, wherein the substrate is comprised of a flexible material.

20. The solar panel of claim 11, wherein the interconnect layout includes one or more bypass diode circuits.

21. A method of forming a photovoltaic cell comprising of an array of micro-tiles, comprising the steps of:
etching a plurality of slots in at least a portion of a crystalline silicon material to form a plurality of elongated, substantially parallel micro-tiles extending from one edge of the silicon material through substantially to the other edge of the silicon material; and
forming a hinge selectively on at least one edge of the silicon material.

22. The method of claim 21, further comprising the step of:
engaging the hinge such that the plurality of micro-tiles are separated from the crystalline silicon material in long strips.

23. The method of claim 22, where the plurality of micro-tiles are separated in a fanfold like manner.

24. The method of claim 22, further comprising separating the micro-tiles from the hinge to form a plurality of silicon micro-tiles.

25. The method of claim 24, wherein the silicon micro-tiles are loaded on a temporary substrate forming a column of micro-tiles.

26. The method of claim 25, wherein the silicon micro-tiles are each loaded on the temporary substrate in a random orientation with respect to the other silicon micro-tiles.

27. The method of claim 21, further comprising:
moving the silicon micro-tiles using an array of vacuum pads.

28. The method of claim 21, further comprising: forming at least one array of silicon micro-tiles.

29. The method of claim 21, further comprising: moving the silicon micro-tiles using a heat release tape or a vacuum pad.

30. The method of claim 21, further comprising: forming contacts on at least one of the top, rear, and side edges of one or more of the silicon micro-tiles.

31. The method of claim 21, further comprising: applying at least one dopant to at least one surface of the silicon micro-tiles.

32. The method of claim 21 further comprising: texturing at least one surface of the silicon micro-tiles.

33. The method of claim 21 further comprising: depositing an antireflective coating on at least one surface of the silicon micro-tiles.

34. The method of claim 21 further comprising: selectively doping at least one surface of at least one of the silicon micro-tiles.

35. The method of claim 21 wherein the step of etching comprises applying one or more etchants to opposing edges of the crystalline silicon material.

36. The method of claim 21 wherein the step of etching comprises applying one or more etchants to one edge of the crystalline silicon material.
